(19) United States
(12) Patent Application Publication
(10) Pub. No.: US 2025/0271598 A1
(43) Pub. Date: Aug. 28, 2025

(54) ANTI-REFLECTION LAYER AND DISPLAY APPARATUS HAVING THE SAME

(71) Applicant: Samsung Display Co., Ltd., Yongin-si (KR)

(72) Inventors: Jaesul An, Yongin-si (KR); Youngok Park, Yongin-si (KR)

(21) Appl. No.: 18/956,582

(22) Filed: Nov. 22, 2024

(30) Foreign Application Priority Data
Feb. 22, 2024 (KR) 10-2024-0026037

(51) Int. Cl. G02B 1/115; H05K 5/03

(52) U.S. Cl. CPC G02B 1/115; H05K 5/03

(57) ABSTRACT

A display apparatus a display panel including a display element; a cover window on the display panel, and an anti-reflection layer on the cover window. The anti-reflection layer includes a first layer having a refractive index, a second layer on the first layer and having a refractive index less than the refractive index of the first layer, the first layer including a first surface facing the second layer and a second surface facing the cover window, and the first layer including a plurality of holes defined therein and open at both the first surface and the second surface.

This application claims priority to Korean Patent Application No. 10-2024-0026037, filed on Feb. 22, 2024, and all the benefits accruing therefrom under 35 U.S.C. § 119, the disclosure of which is incorporated by reference herein in its entirety.

### BACKGROUND

### 1. Field

One or more embodiments relate to a display apparatus, and more particularly, to a display apparatus with improved durability.

### 2. Description of the Related Art

Display apparatuses may include various members coupled to each other. Specifically, a display apparatus include a display panel including a display element and a cover window for protecting the display panel, where the display panel and the cover window are coupled to each other. This display apparatus may further include an anti-reflection layer to reduce the reflectivity of light incident from outside of the display apparatus so as to improve the visibility of the display apparatus.

Display apparatuses may be used in various electronic apparatuses. For example, display apparatuses may be mobile electronic apparatuses such as a mobile electronic apparatus. Such an electronic apparatus may be a foldable electronic device in which a portion of a display surface is folded so as to increase an area of the display surface while reducing an overall size of the electronic devices.

### SUMMARY

Display apparatuses in the art have a drawback in that an anti-reflection layer is damaged when the display apparatus is folded.

One or more embodiments include a display apparatus with improved durability. However, this objective is only an example, and the scope of one or more embodiments are not limited thereto.

Additional aspects will be set forth in part in the description which follows and, in part, will be apparent from the description, or may be learned by practice of the presented embodiments of the disclosure.

According to one or more embodiments, a display apparatus includes a display panel including a display element, a cover window disposed on the display panel, and anti-reflection layer including a first layer disposed on the cover window and a second layer disposed on the first layer and having a refractive index less than a refractive index of the first layer, where the first layer includes a first surface facing the second layer and a second surface facing the cover window, and the first layer includes a plurality of holes passing through the first surface and the second surface.

A density of the second layer may be greater than a density of the first layer.

Each of the first layer and the second layer may include at least one of silicon oxide, silicon nitride, and titanium oxide.

A size of each of the plurality of holes may be about 1 nanometer (nm) to about 10 micrometers (μm).

A distance between adjacent holes from among the plurality of holes may be about 1 nanometer (nm) to about 10 μm.

The second layer may not include a hole with a size of about 1 nm or more.

The anti-reflection layer may further include a third layer between the first layer and the second layer, and the third layer may include at least one of silicon oxide, silicon nitride, and titanium oxide.

The third layer may include a plurality of sub-layers.

A refractive index of the third layer may be less than the refractive index of the first layer and greater than the refractive index of the second layer.

The display apparatus may be foldable in an out-folding manner so that a portion of the first surface and another portion of the first surface face in opposite directions.

According to one or more embodiments, a display apparatus includes a display panel including a display element, a cover window disposed on the display panel, and anti-reflection layer including a first layer disposed on the cover window and a second layer disposed on the first layer and having a refractive index less than a refractive index of the first layer, where the first layer includes a first surface facing the second layer and a second surface facing the cover window, and the first layer includes a plurality of grooves disposed on the second surface.

A density of the second layer may be greater than a density of the first layer.

Each of the first layer and the second layer may include at least one of silicon oxide, silicon nitride, and titanium oxide.

A size of each of the plurality of grooves may be about 1 nm to about 10 μm.

A distance between adjacent grooves from among the plurality of grooves may be about 1 nm to about 10 μm.

The second layer may not include a groove of about 1 nm or more.

The anti-reflection layer may further include a third layer between the first layer and the second layer, and the third layer may include at least one of silicon oxide, silicon nitride, and titanium oxide.

The third layer may include a plurality of sub-layers.

A refractive index of the third layer may be less than the refractive index of the first layer and greater than the refractive index of the second layer.

The display apparatus may be foldable in an out-folding manner so that a portion of the first surface and another portion of the first surface face in opposite directions.

Other aspects, features, and advantages other than those described above would become apparent from the detailed description, claims, and drawings for carrying out one or more embodiments below.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a side view schematically illustrating a display apparatus according to an embodiment;

FIG. 3 is a cross-sectional view schematically illustrating a cross-section taken along line I-I′ of the display apparatus of FIG. 1;

FIG. 4 is an equivalent circuit diagram of a pixel circuit included in a display panel of FIG. 3;

FIG. 5 is an enlarged cross-sectional view of a display panel of a display apparatus, at a display area, according to an embodiment;

FIG. 6 is an enlarged cross-sectional view schematically illustrating region A of the display apparatus of FIG. 3;

FIG. 7 is a plan view schematically illustrating a portion of a first layer included in a display apparatus according to an embodiment;

FIG. 8 is a cross-sectional view schematically illustrating a display apparatus according to an embodiment;

FIG. 9 is a cross-sectional view schematically illustrating a display apparatus according to an embodiment;

FIG. 10 is a cross-sectional view schematically illustrating a portion of a display apparatus according to an embodiment; and

FIG. 11 is a plan view schematically illustrating a portion of a first layer included in a display apparatus according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Herein, it will be understood that although terms such as “first” and “second” may be used herein to describe various elements, these elements should not be limited by these terms and these terms are only used to distinguish one element from another element.

Herein, an expression used in the singular encompasses the expression of the plural, unless it has a clearly different meaning in the context. For example, within the Figures and the text of the disclosure, a reference number indicating a singular form of an element may also be used to reference a plurality of the singular element.

Herein, it will be further understood that the terms “comprises” and/or “comprising” used herein specify the presence of stated features or elements, but do not preclude the presence or addition of one or more other features or elements.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. Herein, “A and/or B” indicates A, B, or A and B. In addition, “at least one of A and B” indicates A, B, or A and B.

Herein, when various elements such as layers, films, areas, plates, or the like are described to be disposed “on” other elements, it includes not only a case of being disposed “directly on” the other elements but also a case in which other elements are in between. In contrast, when elements such as layers, films, areas, plates, or the like are described as being related such as “directly on” other elements, no other element is therebetween.

Herein, when films, areas, elements, or the like are described to be connected, it includes a case where the films, the areas, the elements, or the like are directly connected, or/and a case where the films, the areas, the elements, or the like are indirectly connected with other films, areas, or elements therebetween. For example, herein, when it is described that films, areas, elements, or the like are electrically connected, it indicates a case where the films, areas, elements, or the like are directly electrically connected, or/and a case where the films, areas, the elements, or the like are indirectly electrically connected with other films, areas, or elements therebetween.

Herein, an x-axis, a y-axis, and a z-axis are not limited to the three axes in the Cartesian coordinate system, but can be interpreted in a broad sense including the same. For example, the x-axis, the y-axis, and the z-axis may be orthogonal to each other, but may also refer to directions which are not orthogonal to each other.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Herein, when an embodiment can be implemented differently, a specific process sequence may be performed differently from the described sequence. For example, two processes described in succession may be performed substantially at the same time, or may be performed in an order opposite to the described sequence.

Hereinafter, embodiments will be described with reference to the accompanying drawings, where like reference numerals refer to like elements throughout and a repeated description thereof is omitted. In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

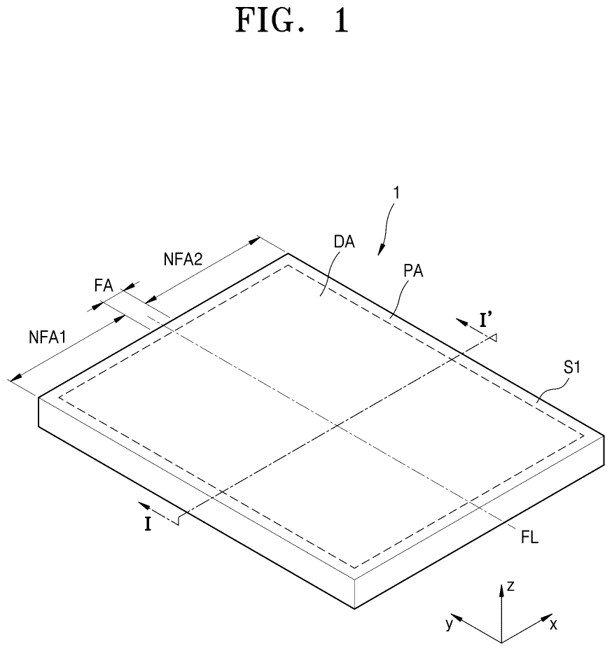

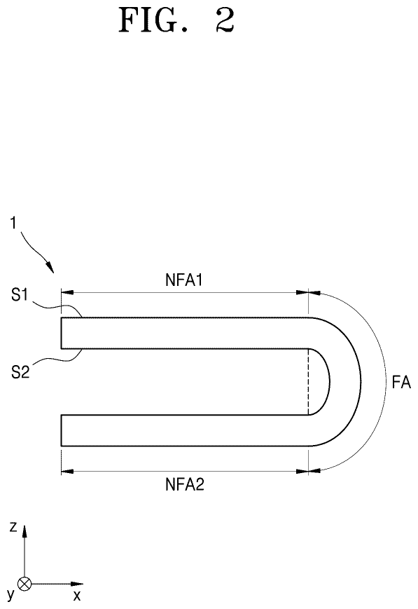

FIG. 1 is a perspective view schematically illustrating a display apparatus 1 according to an embodiment, and FIG. 2 is a side view schematically illustrating the display apparatus 1 according to an embodiment. Specifically, FIG. 1 shows the display apparatus 1 in an unfolded state, while FIG. 2 shows the display apparatus 1 in a folded state.

It may be understood that an x-axis direction refers to a horizontal direction of the display apparatus 1, a y-axis direction refers to a vertical direction of the display apparatus 1, and a z-axis direction refers to a thickness direction of the display apparatus 1. For convenience of description, hereinbelow, when the display apparatus 1 or surfaces of each element constituting the display apparatus 1 are referred to, a surface facing a direction in which the display apparatus 1 provides an image (i.e., a +z direction based on FIG. 1) is referred to as an upper surface, and an opposite surface to the surface is referred to as a lower surface. However, one or more embodiments are not limited thereto. The display apparatus 1 or the surface of each element constituting the display apparatus 1, and the opposite surface to the surface may be referred to as a first surface and a second surface, respectively. Alternatively, the display apparatus 1 or the surface of each element constituting the display apparatus 1 and the opposite surface to the surface may be referred to as a third surface and a fourth surface, respectively.

Referring to FIGS. 1 and 2, the display apparatus 1 may display a moving image or a still image. The display apparatus 1 may be any electronic apparatus which provides a display screen. For example, the display apparatus 1 may include televisions, laptops, monitors, billboards, Internet of Things (IoT), mobile phones, smartphones, tablet personal computers (PCs), electronic watches, smart watches, watchphones, head-mounted displays, mobile communication terminals, electronic notebooks, electronic books, portable multimedia players (PMPs), navigations, game consoles, digital cameras, camcorders, or the like, which provide display screens.

The display apparatus 1 may have a polygonal shape such as rectangular shapes in the plan view. For example, the display apparatus 1 may have a rectangular shape with a horizontal length less than a vertical length, a rectangular shape with the horizontal length greater than the vertical length, or a square shape. Alternatively, the display apparatus 1 may have various planar shapes such as elliptical shapes or circular shapes. In FIG. 1, the display apparatus 1 has a rectangular shape with a horizontal length less than a vertical length. However, one or more embodiments are not limited thereto.

The display apparatus 1 may include a first surface S1 and a second surface S2 which is opposite to the first surface S1. In an embodiment, the first surface S1 may be an upper surface of the display apparatus 1 (in the +z direction). The second surface S2 may be a lower surface of the display apparatus 1 (in a −z direction). The display apparatus 1 may display an image on the first surface S1. In other words, the first surface S1 may include a display surface. Specifically, the first surface S1 may include a display area DA and a peripheral area PA.

The display area DA is an area (e.g., a planar area) which provides images, and the display area DA may provide an image through an array of a plurality of two-dimensionally arranged pixels. Each of the pixels of the display apparatus 1 is an area at which light of a certain color is emitted, and the display apparatus 1 may provide an image by using light emitted from the pixels. For example, each pixel may emit red, green, or blue light. The display area DA may have a polygonal shape, including a rectangle, as shown in FIG. 1. For example, the display area DA may have a rectangular shape with a horizontal length less than a vertical length, a rectangular shape with the horizontal length greater than the vertical length, or a square shape. Alternatively, the display area DA may have various shapes such as elliptical shapes or circular shapes.

The peripheral area PA is a non-display area which does not provide images, and a driver or main power line for providing electrical signals or power to pixel circuits PC may be arranged in the peripheral area PA. The peripheral area PA may include a pad at which an electronic element or a printed circuit board may be electrically connected to the display apparatus 1. The peripheral area PA may surround the display area DA entirely.

The display apparatus 1 may be foldable. In other words, at least a portion of the display apparatus 1 may have flexibility, and the display apparatus 1 may be folded as the portion having flexibility is bent. Accordingly, a folding area and a non-folding area, which is an unbendable area provided on at least one side of the folding area, may be included. Herein, “non-folding” refers to not folded, which includes cases in which an element is not flexible and hard and is not foldable, but also cases in which an element is flexible but remains unfolded or flat even when the display apparatus 1 is folded at the folding area. The display apparatus 1 may display images not only in the non-folding area but also in the folding area.

Specifically, the display apparatus 1 may be folded in an out-folding manner. For example, the display apparatus 1 may be folded such that a portion of the first surface S1 of the display apparatus 1 and another portion of the first surface S1 of the display apparatus 1 face in opposite directions from each other (e.g., out-folded). In other words, the display apparatus 1 may be folded such that a portion of the second surface S2 of the display apparatus 1 and another portion of the second surface S2 of the display apparatus 1 face each other. Accordingly, the display surface of the display apparatus 1 may be visible from outside the display apparatus 1 which is out-folded, such as by users, even when the display apparatus 1 is folded.

As shown in FIG. 1, the display apparatus 1 may include a first non-folding area NFA1, a second non-folding area NFA2, and a foldable area FA. The first non-folding area NFA1 and the second non-folding area NFA2 may be unfoldable areas or areas which are unfolded, and the foldable area FA may be an area which has foldability and at which the display apparatus 1 and various layers or components thereof are foldable.

The foldable area FA may extend in a direction which crosses an imaginary line connecting the foldable area FA to the second non-folding area NFA2. Specifically, when the display apparatus 1 is unfolded, the first non-folding area NFA1 and the second non-folding area NFA2 may be arranged to be spaced apart from each other in a first direction (e.g., the x-axis direction). The foldable area FA may be arranged between the first non-folding area NFA1 and the second non-folding area NFA2. Specifically, the first non-folding area NFA1 may be adjacent to one side of the foldable area FA, and the second non-folding area NFA2 may be adjacent to another side of the foldable area FA. When the display apparatus 1 is unfolded, the foldable area FA may extend in a second direction (e.g., the y-axis direction) crossing the first direction.

A folding line FL may be provided as a virtual line within the folding line FL in the second direction (e.g., the y-axis direction), which is the direction in which the folding line FL extends. Accordingly, the display apparatus 1 may be folded in the foldable area FA. The foldable area FA and the folding line FL of the foldable area FA may overlap an area in which an image of the display apparatus 1 is displayed, and when the display apparatus 1 is folded, a portion at which the image is displayed may be folded.

In FIG. 1, for convenience of description, the first non-folding area NFA1 and the second non-folding area NFA2 have equal or similar planar areas, and the display apparatus 1 includes one foldable area FA. However, one or more embodiments are not limited thereto. For example, the first non-folding area NFA1 and the second non-folding area NFA2 may have different planar areas from each other. In addition, the display apparatus 1 may include a plurality of foldable areas FA. In this case, the plurality of non-folding areas may be arranged to be spaced apart from each other, and each of the plurality of foldable areas FA may be arranged between the non-folding areas. The display apparatus 1 may be foldable at each foldable area FA with respect to the folding line FL thereof, and the foldable area FA may be provided in plurality.

In FIG. 1, the folding line FL passes through a center of the foldable area FA, and a planar area of the foldable area FA is symmetrical with respect to the folding line FL. However, one or more embodiments are not limited thereto. For example, the folding line FL may be provided asymmetrically within the foldable area FA.

As shown in FIG. 2, the display apparatus 1 may be folded with respect to the folding line FL so that the second surface S2 of the first non-folding area NFA1 and the second surface S2 of the second non-folding area NFA2 face each other. In other words, the display apparatus 1 may be out-folded such that the first surface S1 of the first non-folding area NFA1 and the first surface S1 of the second non-folding area NFA2 face in opposite directions from each other. In other words, the display apparatus 1 may be folded by using an out-folding manner. As the foldable area FA of the display apparatus 1 is bent, the display area DA of the first non-folding area NFA1 and the display area DA of the second non-folding area NFA2 may be arranged to face in opposite directions from each other. Accordingly, the display area DA of the display apparatus 1 may be visible from outside the display apparatus 1 (e.g., to users) even when the display apparatus 1 is folded.

Even when the display apparatus 1 is folded, the foldable area FA may extend in a direction which crosses an imaginary line connecting the first non-folding area NFA1 to the second non-folding area NFA2. Specifically, when the display apparatus 1 is folded, the foldable area FA may extend in the second direction (e.g., the y-axis direction), which crosses an imaginary straight line connecting the first non-folding area NFA1 to the second non-folding area NFA2 (e.g., a straight line parallel to the z-axis direction).

The foldable area FA may be bent and unbent repeatedly. In other words, the display apparatus 1 may be a foldable display apparatus.

The term “folded” as used herein does not refer to a fixed shape, but means that the shape is transformed from an original form to another form and is foldable, curvable, or bendable to be folded, curved, or bent along one or more specific lines or axes, that is, the folding line FL. Accordingly, in FIG. 2, the display apparatus 1 is folded such that the first surface S1 of the first non-folding area NFA1 and the first surface S1 of the second non-folding area NFA2 are arranged parallel to each other along the thickness direction of the display apparatus 1 and face in opposite directions from each other. However, one or more embodiments are not limited thereto. For example, the display apparatus 1 may be folded such that the foldable area FA of the first non-folding area NFA1 and the first surface S1 of the second non-folding area NFA2 form a certain angle (e.g., an acute angle, a right angle, or an obtuse angle) with the foldable area FA therebetween.

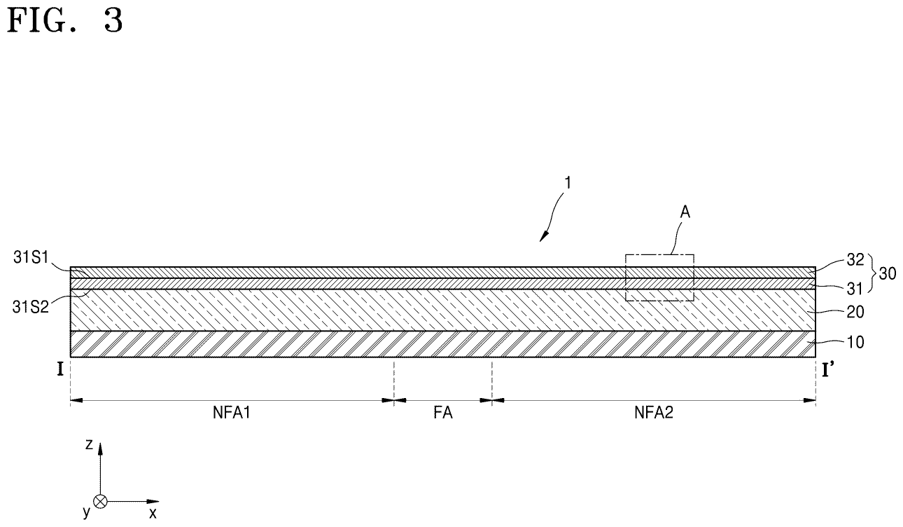

FIG. 3 is a cross-sectional view schematically illustrating a cross-section taken along line I-I′ of the display apparatus 1 of FIG. 1.

As shown in FIG. 3, the display apparatus 1 may include a display panel 10, a cover window 20, and an anti-reflection layer 30. However, the display apparatus 1 may further include various other elements in addition to the elements shown in FIG. 3.

The display panel 10 may be disposed under the cover window 20. The display panel 10 may display an image. In other words, it may be understood that images provided by the display apparatus 1 are implemented by the display panel 10. The display panel 10 may include a plurality of display elements, and each of the plurality of display elements may emit red, green, or blue light. Accordingly, the display panel 10 may display images through the light emitted from the plurality of display elements. In other words, one display element may correspond to one pixel. The images displayed on the display panel 10 may be provided to outside of the display apparatus 1 (e.g., to a user) through the cover window 20 which is transparent.

The cover window 20 may be disposed on the upper surface of the display panel 10. As being ‘disposed on,’ elements may contact each other, such as to form an interface therebetween. According to an embodiment, the cover window 20 may be disposed to cover the upper surface of display panel 10. This cover window 20 may function to protect the upper surface of the display panel 10. In addition, since the cover window 20 forms an exterior of the display apparatus 1, the cover window 20 may include flat and curved surfaces corresponding to the shape or profile of the display apparatus 1. The cover window 20 may have a high transmittance to transmit light emitted from the display panel 10 and may have a small thickness to minimize weight of the display apparatus 1. In addition, the cover window 20 may have high strength and hardness to protect the display panel 10 from external shock.

Although not shown, an adhesive member may be positioned between the display panel 10 and the cover window 20. The adhesive member may include at least one of optical clear resin (OCR), an optical clear adhesive (OCA), and a pressure sensitive adhesive (PSA). This adhesive member may serve to couple the display panel 10 and the cover window 20 to each other.

The anti-reflection layer 30 may be disposed on the cover window 20. The anti-reflection layer 30 may reduce reflectivity of light incident from the outside (e.g., outside of the display apparatus 1). The anti-reflection layer 30 may include a plurality of sub-layers. For example, as shown in FIG. 3, the anti-reflection layer 30 may include a first layer 31 and a second layer 32. The second layer 32 may be disposed on the first layer 31. Specifically, the first layer 31 may be disposed on the cover window 20, and the second layer 32 may be disposed on the first layer 31. In other words, the first layer 31 may be arranged closest to the cover window 20 from among the sub-layers of the anti-reflection layer 30, and the second layer 32 may be arranged farthest away from the cover window 20 from among the sub-layers of the anti-reflection layer 30. In an embodiment, a protective layer for protecting the cover window 20 may be positioned between the anti-reflection layer 30 and the cover window 20. In other words, the protective layer may be disposed on the cover window 20, and the first layer 31 may be disposed on that protective layer. Hereinbelow, for convenience of description, it is described that the first layer 31 is disposed on the cover window 20.

The first layer 31 may include a third surface 31S1 and a fourth surface 31S2 which is opposite to the third surface 31S1. In an embodiment, the third surface 31S1 may be an upper surface of the first layer 31 (in the +z direction). The fourth surface 31S2 may be a lower surface of the first layer 31 (in a −z direction). In other words, the third surface 31S1 may be a surface facing the second layer 32, and the fourth surface 31S2 may be a surface facing the cover window 20. In other words, the third surface 31S1 may be a surface adjacent to (e.g., closest to) the second layer 32, and the fourth surface 31S2 may be a surface adjacent to the cover window 20. In the claims, the third surface 31S1 may be referred to as a first surface, and the fourth surface 31S2 may be referred to as a second surface.

As described above, when the display apparatus 1 is folded in the out-folding manner, the display apparatus 1 may be folded such that a portion of the third surface 31S1 of the first layer 31 and another portion of the third surface 31 S1 of the first layer 31 face in opposite directions from each other. In other words, the display apparatus 1 may be out-folded such that a portion of the fourth surface 31S2 of the first layer 31 and another portion of the fourth surface 31S2 of the first layer 31 face each other. The first layer 31 and the second layer 32 may have different refractive indices from each other. In other words, the second layer 32 may have a refractive index different from a refractive index of the first layer 31. The anti-reflection layer 30 is described in detail below.

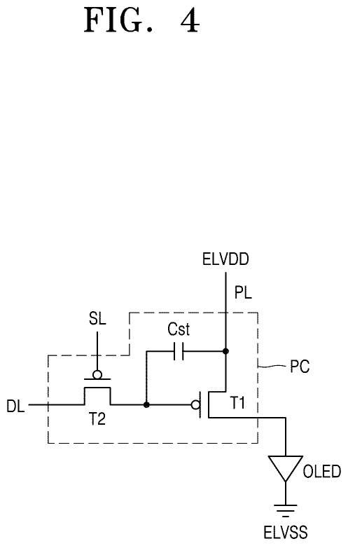

FIG. 4 is an equivalent circuit diagram of a pixel circuit PC included in the display panel 10 of FIG. 3. The pixel circuit PC may be electrically connected to a display element, and one display element may correspond to one pixel. In FIG. 4, an organic light-emitting diode OLED is shown as the display element. In an embodiment, the display element may emit red, green, or blue light.

The pixel circuit PC may include a first transistor T1, a second transistor T2, and a storage capacitor Cst. The second transistor T2, which is a switching transistor, is connected to signal lines such as a scan line SL and a data line DL and may be turned on in response to an electrical signal such as a switching signal received via the scan line SL and may transfer an electrical signal such as a data signal received via the data line DL to the first transistor T1. The storage capacitor Cst may have one terminal electrically connected to the second transistor T2 and another terminal electrically connected to a driving voltage line PL and may store a voltage corresponding to a difference between a voltage received from the second transistor T2 and a driving power voltage ELVDD supplied to the driving voltage line PL.

The first transistor T1, which is a driving transistor, may be connected to the driving voltage line PL and the storage capacitor Cst and may control a magnitude of a driving current (e.g., electrical current(flowing through the organic light-emitting diode OLED from the driving voltage line PL to correspond to a voltage value stored in the storage capacitor Cst. The organic light-emitting diode OLED may emit light having a certain luminance according to the driving current. An opposite electrode of the organic light-emitting diode OLED may receive an electrode power voltage ELVSS.

In FIG. 4, the pixel circuit PC includes two transistors and one storage capacitor. However, one or more embodiments are not limited thereto. For example, the number of transistors and the number of storage capacitors may be variously modified depending on a design of the pixel circuit PC.

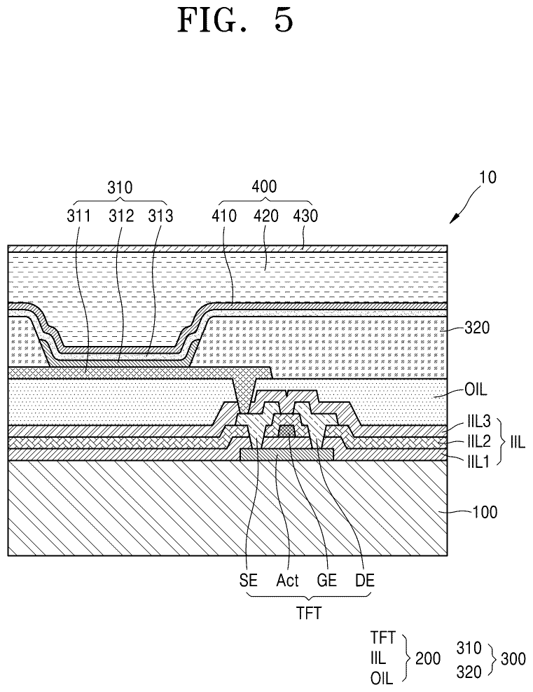

FIG. 5 is a schematic cross-sectional view of the display panel 10 of the display apparatus 1, at the display area DA, according to an embodiment. However, as recognized by those skilled in the art, the display panel 10 may further include various other elements in addition to the elements shown in FIG. 5.

As shown in FIG. 5, the display panel 10 may include a substrate 100, and a transistor TFT and a display element which are formed (or provided) by a plurality of layers formed on the substrate 100. Specifically, the display panel 10 may include the substrate 100, a pixel circuit layer 200, a display element layer 300, and an encapsulation layer 400.

The substrate 100 may include glass, metal, or polymer resin. The substrate 100 has flexible or bendable properties. In this case, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may have a multi-layer structure including two layers including the polymer resin described above and a barrier layer including an inorganic material (e.g., silicon oxide (SiOₓ), silicon nitride (SiNₓ), silicon oxynitride (SiOₓN_{y}), or the like), and various modifications may be made.

The pixel circuit layer 200 may be disposed on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, FIG. 5 shows one transistor TFT, and this transistor TFT may correspond to the first transistor T1 described above.

The semiconductor layer Act may be disposed on the substrate 100. The semiconductor layer Act may include polysilicon. Alternatively, the semiconductor layer Act may include amorphous silicon, oxide semiconductor, organic semiconductor, or the like. In an embodiment, the semiconductor layer Act may include a channel region and a source region and a drain region which are respectively arranged at opposite sides of the channel region.

The gate insulating layer IIL1 may be disposed on the semiconductor layer Act and the substrate 100. The gate insulating layer IIL1 may include an inorganic insulating material such as SiOₓ, SiNₓ, SiOₓN_{y}, aluminum oxide (Al₂O₃), titanium oxide (TiOₓ), tantalum oxide (Ta₂O₅), hafnium oxide (HfO₂), or zinc oxide (ZnOₓ). ZnOₓ may include zinc oxide (ZnO) and/or zinc peroxide (ZnO₂).

The gate electrode GE may be disposed on the gate insulating layer IIL1. In other words, the gate insulating layer IIL1 may be positioned between the semiconductor layer Act and the gate electrode GE, thereby insuring insulation (e.g., electric insulation) between the semiconductor layer Act and the gate electrode GE. The gate electrode GE may overlap the channel region of the semiconductor layer Act. The gate electrode GE may include a low-resistance metal material. In an embodiment, the gate electrode GE may include a conductive material, including molybdenum (Mo), aluminum (AI), copper (Cu), titanium (Ti), etc., and may have a single-layer or multi-layer structure including the conductive materials described above.

The first interlayer insulating layer IIL2 may be disposed on the gate electrode GE and the gate insulating layer IIL1. The first interlayer insulating layer IIL2 may include an inorganic insulating material such as SiOₓ, SiNₓ, SiOₓN_{y}, Al₂O₃, TiOₓ, Ta₂O₅, HfO₂, or ZnOₓ.

The source electrode SE and the drain electrode DE may be disposed on the first interlayer insulating layer IIL2. Each of the source electrode SE and the drain electrode DE may be connected to the semiconductor layer Act through (or at) a contact hole defined in the gate insulating layer IIL1 and the first interlayer insulating layer IIL2. At least one of the source electrode SE and the drain electrode DE may include a conductive material such as Mo, Al, Cu, or Ti, and may have a single-layer or multi-layer structure including the conductive materials. In an embodiment, at least one of the source electrode SE and the drain electrode DE may have a multi-layer structure of Ti/Cu/Ti.

The second interlayer insulating layer IIL3 may be disposed on the source electrode SE, the drain electrode DE, and the first interlayer insulating layer IIL2. The second interlayer insulating layer IIL3 may include an inorganic insulating material such as SiOₓ, SiNₓ, SiOₓN_{y}, Al₂O₃, TiOₓ, Ta₂O₅, HfO₂, or ZnOₓ.

The organic insulating layer OIL may be disposed on the second interlayer insulating layer IIL3. The organic insulating layer OIL may approximately planarize an upper portion of the pixel circuit layer 200. For example, this organic insulating layer OIL may include an organic material such as acryl, benzocyclobutene (BCB), or hexamethyldisiloxane (HMDSO). In FIG. 5, the organic insulating layer OIL includes one layer. However, the organic insulating layer OIL may have a plurality of layers, and various modifications may be made.

The display element layer 300 may be disposed on the pixel circuit layer 200. The display element layer 300 may include a display element 310 and a pixel-defining layer 320. The display element 310 may be electrically connected to the transistor TFT. For example, the display element 310 may be an organic light-emitting diode having a pixel electrode 311, an opposite electrode 313, and an intermediate layer 312, which is disposed therebetween and includes an emission layer. The fact that the display element 310 is electrically connected to the transistor TFT may be understood that the pixel electrode 311 of the organic light-emitting diode is electrically connected to the transistor TFT.

The pixel electrode 311 may be electrically connected to the transistor TFT by contacting (e.g., physically and/or electrically) with any one of the source electrode SE and the drain electrode DE through a contact hole defined in the second interlayer insulating layer IIL3 and the organic insulating layer OIL. The pixel electrode 311 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 311 may include a reflective film including silver (Ag), magnesium (Mg), aluminum (Al), platinum (Pt), palladium (Pd), gold (Au), nickel (Ni), neodymium (Nd), iridium (Ir), chrome (Cr), or a combination thereof. In an embodiment, the pixel electrode 311 may further include a film formed of ITO, IZO, ZnO, or In₂O₃, over/under the reflective film described above.

The pixel-defining layer 320 may cover an edge of the pixel electrode 311. The pixel-defining layer 320 may include (or define) a pixel opening portion, and the pixel opening portion may overlap the pixel electrode 311. The pixel opening portion may define a light emission area at which light is emitted from the display element 310. A solid portion of the pixel-defining layer 320 which defines the pixel opening may include an organic insulating material and/or an inorganic insulating material. In some embodiments, the pixel-defining layer 320 may include a light-blocking material.

The intermediate layer 312 may be disposed on the pixel electrode 311 and the pixel-defining layer 320. The intermediate layer 312 may include a low-molecular-weight or polymer material. When the intermediate layer 312 includes the low-molecular-weight material, the intermediate layer 312 may have a single or complex laminated structure of a hole injection layer (HIL), a hole transport layer (HTL), an emission layer (EML), an electron transport layer (ETL), an electron injection layer (EIL), or the like, and may be formed by vacuum deposition. When the intermediate layer 312 includes the polymer material, the intermediate layer 312 may have a structure including an HTL and an EML. In this case, the HTL may include poly(3,4-ethylenedioxythiophene) (PEDOT), and the EML may include a polymer material such as polyphenylene vinylene (PPV)-based or polyfluorene-based. This intermediate layer 312 may be formed by screen printing, inkjet printing, laser induced thermal imaging (LITI), or the like. However, the intermediate layer 312 is not necessarily limited thereto and may have various structures. In addition, the intermediate layer 312 may include a layer which is integrated across a plurality of pixel electrodes 311, or may include a layer patterned to respectively correspond to each of the plurality of pixel electrodes 311.

The opposite electrode 313 may be disposed on the intermediate layer 312 and the pixel-defining layer 320. The opposite electrode 313 may be integrally formed with a plurality of organic light-emitting diodes and may correspond to each of the plurality of pixel electrodes 311. This opposite electrode 313 may include a light-transmitting conductive layer including ITO, In₂O₃, or IZO, and may also include a semi-light-transmitting film including a metal such as Al or Ag. For example, the opposite electrode 313 may be a semi-transmissive film including Mg or Ag.

Since the display element 310 may be easily damaged due to moisture, oxygen, or the like from the outside, the encapsulation layer 400 may cover and protect the display element 310. Referring to FIG. 5, the encapsulation layer 400 may include a first inorganic encapsulation layer 410, an organic encapsulation layer 420, and a second inorganic encapsulation layer 430.

The first inorganic encapsulation layer 410 covers the opposite electrode 313 and may include SiOₓ, SiNₓ, and/or SiOₓN_{y}. However, other layers such as a capping layer (not shown) may be positioned between the first inorganic encapsulation layer 410 and the opposite electrode 313. Since the first inorganic encapsulation layer 410 is formed along a structure thereunder to conform to the cross-sectional profile of such underlying structure, an upper surface of the first inorganic encapsulation layer 410 may not be flat, as shown in FIG. 5.

The organic encapsulation layer 420 covers this first inorganic encapsulation layer 410, and an upper surface thereof may be approximately flat, unlike the first inorganic encapsulation layer 410. This organic encapsulation layer 420 may include one or more materials selected from polyethylene terephthalate, polyethylene naphthalate, polycarbonate, polyimide, polyethylene sulfonate, polyoxymethylene, polyarylate, and HMDSO.

The second inorganic encapsulation layer 430 covers the organic encapsulation layer 420 and may include SiOₓ, SiNₓ, and/or SiOₓN_{y}.

Since the encapsulation layer 400 includes the first inorganic encapsulation layer 410, the organic encapsulation layer 420, and the second inorganic encapsulation layer 430 as described above, even when cracks occur in the encapsulation layer 400, the cracks may be prevented from connecting between the first inorganic encapsulation layer 410 and the organic encapsulation layer 420 or between the organic encapsulation layer 420 and the second inorganic encapsulation layer 430. Through this, the formation of a passage through which moisture or oxygen from the outside permeates into the display panel 10 may be prevented or minimized.

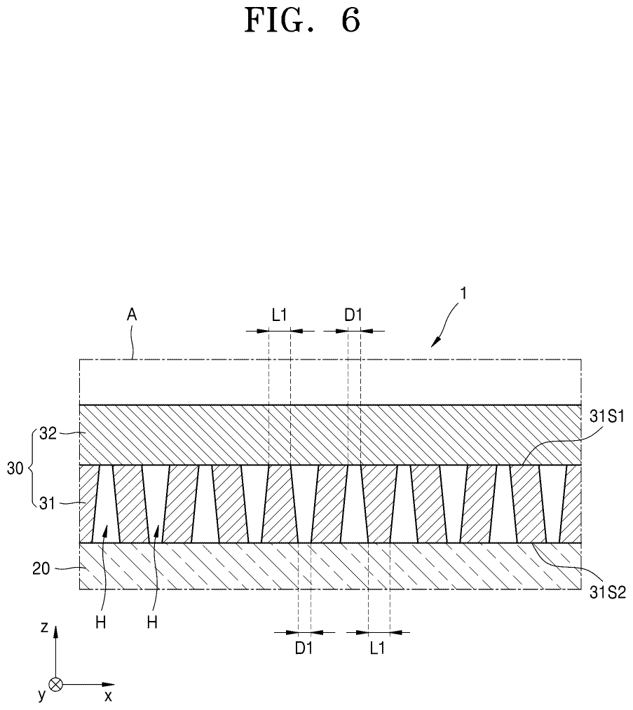

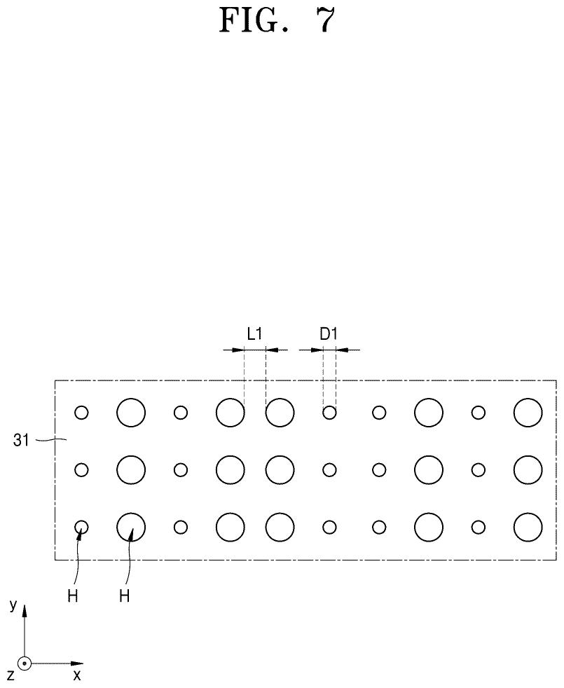

FIG. 6 is an enlarged cross-sectional view schematically illustrating region A of the display apparatus 1 of FIG. 3, and FIG. 7 is a plan view schematically illustrating a portion of the first layer 31 included in the display apparatus 1 according to an embodiment. Specifically, FIG. 7 shows a plan view of the third surface 31S1 of the first layer 31.

As described above, the first layer 31 of the anti-reflection layer 30 may be disposed on the cover window 20, and the second layer 32 may be disposed on the first layer 31. The first layer 31 and the second layer 32 may include an inorganic insulating material. For example, each of the first layer 31 and the second layer 32 may include at least one of SiOₓ, SiNₓ, and TiOₓ. In an embodiment, the first layer 31 may include SiNₓ, and the second layer 32 may include SiOₓ.

The second layer 32 may have a refractive index different from a refractive index of the first layer 31. Specifically, the second layer 32 may have a refractive index less than a refractive index of the first layer 31. In an embodiment, the refractive index of the first layer 31 may be about 1.5 to about 2.6, and the refractive index of the second layer 32 may be about 1.2 to about 1.7.

A refractive index of a layer including an inorganic insulating material or the like may be adjusted by adjusting a content of a component included in the layer (e.g., a content of silicon (Si), a content of oxygen (O), or a content of titanium (Ti)) or by adjusting a thickness of the layer. This adjustment of the refractive index of a layer including an inorganic insulating material or the like by adjusting the content of a component included in the layer or by adjusting the thickness of the layer is a common matter in manufacturing of a display apparatus, and therefore, redundant descriptions thereof are omitted.

As shown in FIGS. 6 and 7, the first layer 31 may include (or define) a hole H, and the hole H may be provided in plurality. In other words, the first layer 31 may include a plurality of holes H. The hole H may have a cross-sectional shape of a truncated cone. Specifically, the hole H may pass through the third surface 31 S1 and the fourth surface 31S2 of the first layer 31, such as to be open at both the upper and lower surfaces of the first layer 31. Each of the plurality of holes H may pass through the third surface 31S1 and the fourth surface 31S2. As shown in FIG. 7, a cross-sectional area (e.g., a planar area) of the hole H which is indicted by a dimension in the x-axis direction may have a circular shape in a cross section (e.g., a plane) perpendicular to a thickness direction (e.g., the z-axis direction) of the display apparatus 1. However, the cross-sectional area of the hole H may decrease or increase along the thickness direction (e.g., the z-axis direction) of the first layer 31.

For example, the cross-sectional area of the hole H may decrease in a direction toward the third surface 31S1 from the fourth surface 31S2. Accordingly, the cross-sectional area of the hole H at the fourth surface 31S2 may be greater than the cross-sectional area of the hole H at the third surface 31 S1. Alternatively, the cross-sectional area of the hole H may increase in a direction toward the third surface 31S1 from the fourth surface 31S2. Accordingly, the cross-sectional area of the hole H at the fourth surface 31 S2 may be less than the cross-sectional area of the hole H at the third surface 31S1. The hole H included in the first layer 31 may not be filled with a portion of another layer disposed over or under the first layer 31. For example, the hole H included in the first layer 31 may not be filled with the second layer 32. In other words, the hole H included in the first layer 31 may be a void or a gap which is empty.

In an embodiment, the hole H may have a cylindrical shape. Specifically, the cross-sectional area of the hole H has a circular shape on a cross section perpendicular to the thickness direction of the display apparatus 1 (e.g., the z-axis direction), and the cross-sectional area of the hole H may be constant in the thickness direction (e.g., the z-axis direction). Hereinbelow, for convenience, it is described that the hole H has the shape of a truncated cone.

In general, when the display apparatus 1 is folded, stress may be applied to the anti-reflection layer 30 including an inorganic material or the like. However, in a case of the display apparatus 1 according to the present embodiment, the first layer 31 of the anti-reflection layer 30 includes a plurality of holes H. These plurality of holes H together with the solid portion of the first layer 31 may have a shape similar to a honeycomb. Accordingly, in the case of the display apparatus 1 according to the present embodiment, even when the display apparatus 1 is folded and stress is applied to the anti-reflection layer 30, the stress applied to the anti-reflection layer 30 may be released. Thus, durability of the anti-reflection layer 30 may not be weak.

A size D1 of the hole H may be about 1 nanometer (nm) or more to less than about 10 micrometers (μm). The size D1 of each of the plurality of holes H may be about 1 nm or more to less than about 10 μm. Herein, the size D1 of the hole H refers to a dimension (e.g., a diameter) of a cross-sectional area of the hole H at a position where the cross-sectional area of the hole H is minimum. For example, when the cross-sectional area of the hole H decreases in the direction toward the third surface 31S1 from the fourth surface 31S2, the size D1 of the hole H may be a diameter of the cross-sectional area of the hole H at the third surface 31 S1. Alternatively, when the cross-sectional area of the hole H increases in the direction toward the third surface 31S1 from the fourth surface 31S2, the size D1 of the hole H may be a diameter of the cross-sectional area of the hole H at the fourth surface 31 S2.

When the size D1 of the hole H is less than 1 nm, the hole H is so small that a stress release effect may not occur. When the size D1 of the hole H is more than 10 μm, the durability of the anti-reflection layer 30 may be reduced since the hole H is too large.

A distance L1 between adjacent holes H from among the plurality of holes H may be about 1 nm or more to less than 10 μm. The distance L1 may correspond to a dimension of a solid portion of the first layer 31 which is between the adjacent holes H. Herein, the distance L1 between adjacent holes H refers to a shortest distance between a sidewall of the first layer 31 at one side of one hole H and a sidewall of the first layer at one side of another hole which is adjacent to the one hole H. Hereinbelow, for convenience, the hole H is referred to as a first hole, and another hole H adjacent to the hole H is referred to as a second hole. For example, where cross-sectional areas of both the first hole and the second hole decrease in the direction toward the third surface 31 S1 from the fourth surface 31 S2, the shortest distance between the first hole and the second hole may be a shortest distance between one side of the first hole at the fourth surface 31S2 and one side of the second hole at the fourth surface 31S2. Alternatively, where the cross-sectional areas of both the first hole and the second hole increase in the direction toward the third surface 31 S1 from the fourth surface 31 S2, the shortest distance between the first hole and the second hole may be a shortest distance between one side of the first hole at the third surface 31S1 and one side of the second hole at the third surface 31S1.

Alternatively, when the cross-sectional area of the first hole decreases in the direction toward the third surface 31S1 from the fourth surface 31S2 and the cross-sectional area of the second hole increases in the direction toward the third surface 31S1 from the fourth surface 31 S2, the shortest distance between the first hole and the second hole may be a shortest distance between one side of the first hole at the third surface 31S1 and one side of the second hole at the third surface 31S1 or a shortest distance between one side of the first hole at the fourth surface 31S2 and one side of the second hole at the fourth surface 31S2. Similarly, when the cross-sectional area of the first hole increases in the direction toward the third surface 31S1 from the fourth surface 31 S2 and the cross-sectional area of the second hole decreases in the direction toward the third surface 31S1 from the fourth surface 31S2, the shortest distance between the first hole and the second hole may be a shortest distance between one side of the first hole at the third surface 31 S1 and one side of the second hole at the third surface 31S1 or a shortest distance between one side of the first hole at the fourth surface 31S2 and one side of the second hole at the fourth surface 31 S2.

When the distance L1 of the adjacent holes H is less than 1 nm, the durability of the anti-reflection layer 30 may be reduced due to too many holes H. When the distance L1 of the adjacent holes H is more than 10 μm, the number of holes H is so small that a stress release effect may not occur.

Unlike the first layer 31, the second layer 32 may not include a hole and may be a solid shape. Specifically, the second layer 32 may not include a hole with a size of 1 nm or more. In other words, the second layer 32 may be dense. Density may refer to an amount of solid (material) portion of a layer within a total planar area thereof, that is, a material density. In other words, a density of the second layer 32 may be greater than a density of the first layer 31. A thickness of this second layer 32 may be about 50% or more of a total thickness of the anti-reflection layer 30. Specifically, the thickness of the second layer 32 may be about 60% or more or about 70% or more of the total thickness of the anti-reflection layer 30. For example, when the total thickness of the anti-reflection layer 30 is about 5 μm, the thickness of the second layer 32 may be about 3 μm. The second layer 32 may not even include grooves to reduce an amount of solid portion of the layer. Specifically, the second layer 32 may not include a groove with a size of 1 nm or more.

In general, when the display apparatus 1 is folded, a relatively large stress may be applied to an outermost layer from among layers included in the anti-reflection layer 30. When the display apparatus 1 is folded, a hole included in the anti-reflection layer 30 may be a starting point of crack generation. Accordingly, cracks may occur in the outermost layer from among the layers included in the anti-reflection layer 30, which may weaken the durability of the anti-reflection layer 30. In other words, when the second layer 32 arranged farthest away from the cover window 20 (e.g., an outermost layer) from among sub-layers of the anti-reflection layer 30 includes a hole, the possibility of cracks occurring may increase, and accordingly, the durability of the anti-reflection layer 30 may be weak.

However, in the case of the display apparatus 1 according to the present embodiment, the second layer 32 may be totally solid or may not include a hole (or groove) with a size of 1 nm or more. That is, the second layer 32 excludes a void having a size of about 1 nanometer or more. Accordingly, in the case of the display apparatus 1 according to the present embodiment, the possibility of cracks occurring in the anti-reflection layer 30 does not increase, and thus, the durability of the anti-reflection layer 30 may not be weak. In other words, the first layer 31 to which a relatively small stress is applied includes a plurality of holes H so that a stress applied to the anti-reflection layer 30 may be released, and the second layer 32 to which a relatively large stress is applied does not include a hole so that the possibility of cracks occurring in the anti-reflection layer 30 may not increase. That is, durability of the anti-reflection layer 30 may not be weak. In other words, the durability of the display apparatus 1 may be improved.

A layer including an inorganic insulating material may be formed through a chemical vapor deposition process or the like. In a process of forming a layer including an inorganic insulating layer or the like, presence or absence of holes in this layer, sizes of the holes, or a distance between the holes may be adjusted by appropriately adjusting deposition conditions (e.g., temperature of a substrate or pressure in a chamber during deposition, or the like). The adjustment of the presence or absence of holes in the layer including an inorganic insulating material or the like, the sizes of the holes, or the distance between the holes by appropriately adjusting the deposition conditions is a common matter in the manufacturing of display apparatuses, and therefore redundant descriptions thereof are omitted.

In FIG. 6, the anti-reflection layer 30 includes only the first layer 31 and the second layer 32. However, one or more embodiments are not limited thereto. For example, the anti-reflection layer 30 may further include an additional sub-layer.

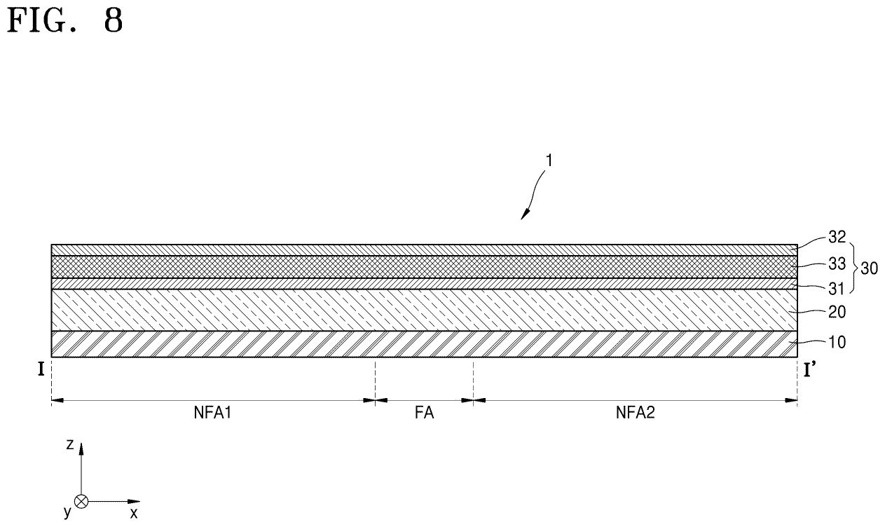

FIG. 8 is a cross-sectional view schematically illustrating the display apparatus 1 according to an embodiment. As shown in FIG. 8, the anti-reflection layer 30 includes the first layer 31 and the second layer 32, and the anti-reflection layer 30 may further include a third layer 33. The third layer 33 may be positioned between the first layer 31 and the second layer 32. Specifically, the third layer 33 may be disposed on the first layer 31, and the second layer 32 may be disposed on the third layer 33.

This third layer 33 may include an inorganic insulating material. For example, the third layer 33 may include at least one of SiOₓ, SiNₓ, and TiOₓ. The third layer 33 may have a refractive index different from the refractive indices of the first layer 31 and the second layer 32. Specifically, the refractive index of the third layer 33 may be less than the refractive index of the first layer 31, and the refractive index of the third layer 33 may be greater than the refractive index of the second layer 32. In other words, the refractive index of the third layer 33 may be less than the refractive index of the first layer 31, and the refractive index of the second layer 32 may be less than the refractive index of the third layer 33.

Even in this case, the first layer 31 of the anti-reflection layer 30 may include a plurality of holes H. These plurality of holes H together with a solid portion of the layer may have a shape similar to a honeycomb. Accordingly, even when the display apparatus 1 is folded and stress is applied to the anti-reflection layer 30, the stress applied to the anti-reflection layer 30 may be released. Thus, the durability of the anti-reflection layer 30 may not be weak. In addition, even in this case, the second layer 32 may not include a hole with a size of 1 nm or more. Accordingly, the possibility of cracks occurring in the anti-reflection layer 30 does not increase, and thus, the durability of the anti-reflection layer 30 may not be weak.

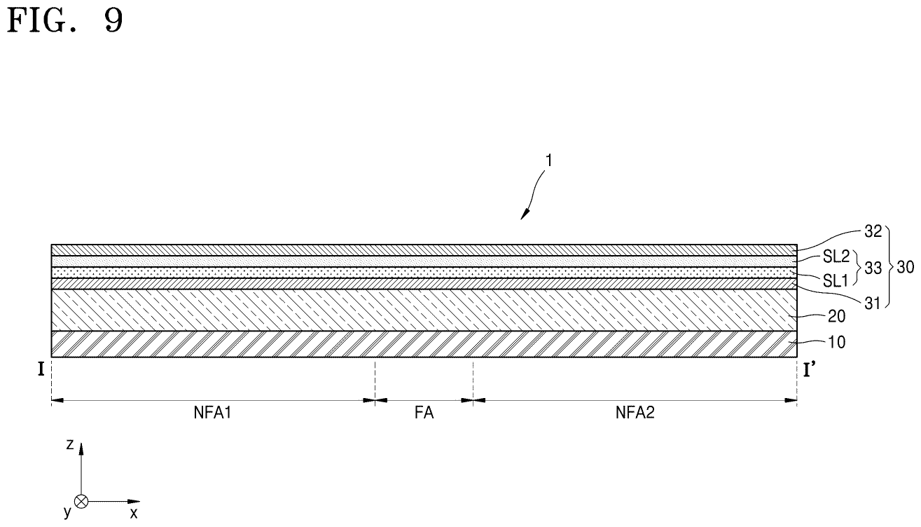

In FIG. 8, the third layer 33 includes one layer (e.g., a monolayer). However, one or more embodiments are not limited thereto. For example, as shown in FIG. 9 which is a cross-sectional view schematically illustrating the display apparatus 1 according to an embodiment, the third layer 33 may include a plurality of sub-layers. Specifically, the third layer 33 may include a first sub-layer SL1 and a second sub-layer SL2 in order from the first layer 31 to the second layer 32. The second sub-layer SL2 may be disposed on the first sub-layer SL1. In other words, the first sub-layer SL1 of the third layer 33 may be disposed on the first layer 31, the second sub-layer SL2 of the third layer 33 may be disposed on the first sub-layer SL1, and the second layer 32 may be disposed on the second sub-layer SL2.

These first sub-layer SL1 and second sub-layer SL2 may include an inorganic insulating material. For example, the first sub-layer SL1 and the second sub-layer SL2 may include at least one of SiOₓ, SiNₓ, and TiOₓ. In an embodiment, the first sub-layer SL1 and the second sub-layer SL2 may include different materials from each other. For example, the first sub-layer SL1 may include SiOₓ, and the second sub-layer SL2 may include SiNₓ. In an embodiment, the first sub-layer SL1 and the second sub-layer SL2 may include a same material as each other. For example, both the first sub-layer SL1 and the second sub-layer SL2 may include SiOₓ. Alternatively, both the first sub-layer SL1 and the second sub-layer SL2 may include SiNₓ.

The first sub-layer SL1 may have a refractive index different from the refractive indices of the first layer 31 and the second layer 32. Specifically, the refractive index of the first sub-layer SL1 may be less than the refractive index of the first layer 31, and the refractive index of the first sub-layer SL1 may be greater than the refractive index of the second layer 32. Similarly, the second sub-layer SL2 may have a refractive index different from the refractive indices of the first layer 31 and the second layer 32. Specifically, the refractive index of the second sub-layer SL2 may be less than the refractive index of the first layer 31, and the refractive index of the second sub-layer SL2 may be greater than the refractive index of the second layer 32. In an embodiment, the first sub-layer SL1 and the second sub-layer SL2 may have different refractive indices from each other. For example, the refractive index of the first sub-layer SL1 may be greater than the refractive index of the second sub-layer SL2. Alternatively, the refractive index of the first sub-layer SL1 may be less than the refractive index of the second sub-layer SL2.

In FIG. 9, the third layer 33 includes two sub-layers. However, one or more embodiments are not limited thereto. For example, the number of sub-layers included in the third layer 33 may be variously modified depending on a design of a light path of light incident on the anti-reflection layer 30. In an embodiment, for example, the anti-reflection layer 30 may include a plurality of layers (layers 31 and 32 with or without layers 33, SL1 and SL2) each having a refractive index. The refractive index of an outermost layer (e.g., the second layer 32) among the plurality of layers being less than all remaining refractive indices, and an innermost layer (e.g., the first layer 31) among the plurality of layers being closest to the display panel 10 and including a plurality of voids (e.g., holes H or grooves G, for example) defined therein.

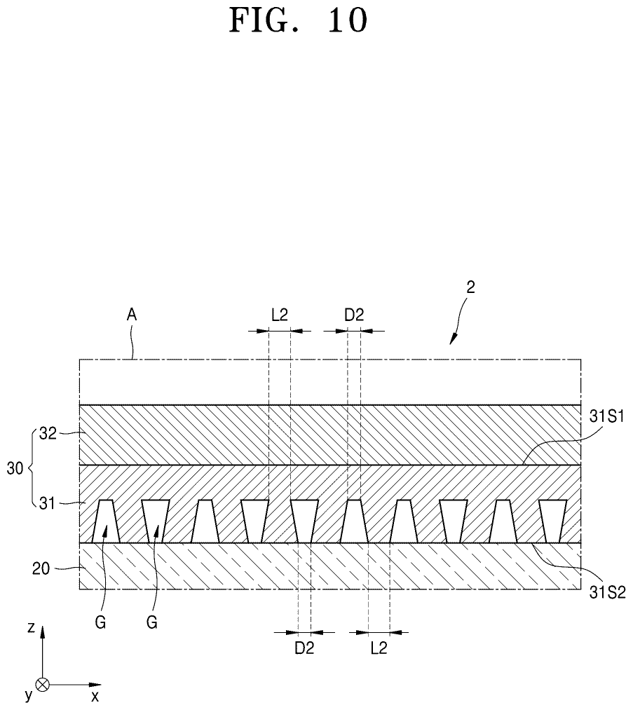

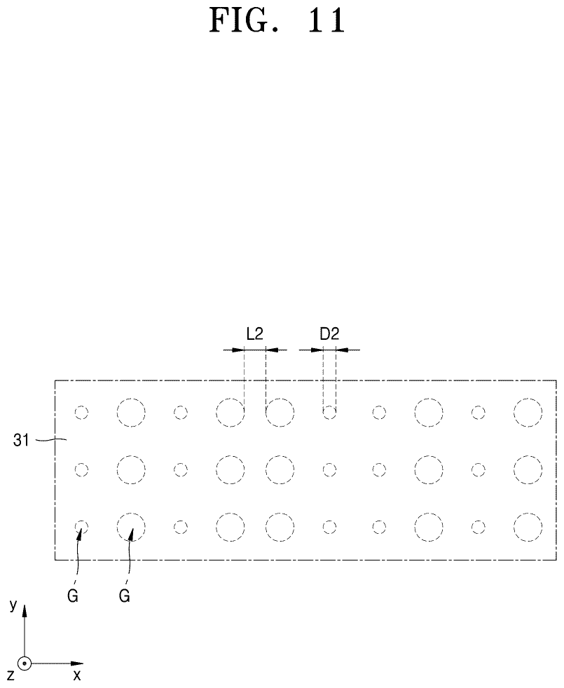

FIG. 10 is a cross-sectional view schematically illustrating a portion of a display apparatus 2 according to an embodiment, and FIG. 11 is a plan view schematically illustrating a portion of the first layer 31 included in the display apparatus 2 according to an embodiment. FIG. 10 is an enlarged cross-sectional view of corresponding to region A of the display apparatus of FIG. 3. Specifically, FIG. 11 shows a plan view of the third surface 31S1 of the first layer 31 within display apparatus 2. However, for convenience of description, cross-sectional areas (dotted lines in FIG. 11) of a plurality of grooves G on a plane adjacent to the third surface 31S1 are shown together. Herein, “a plane adjacent to the third surface 31S1” refers to an imaginary plane parallel to the third surface 31S1 and adjacent to (but spaced apart from) the third surface 31S1 along the thickness direction. The display apparatus 2 according to the present embodiment is similar to the display apparatus 1 described above with reference to FIGS. 1 to 9, and thus, differences from the display apparatus 1 described above with reference to FIGS. 1 to 9 are mainly described below. In FIGS. 10 and 11, the same reference symbols as those of FIGS. 1 to 9 denote the same member, and thus, redundant descriptions thereof are omitted.

The display apparatus 1 described above with reference to FIGS. 1 to 9 may include the display panel 10, the cover window 20, and the anti-reflection layer 30, and the anti-reflection layer 30 may include the first layer 31 and the second layer 32. As shown in FIG. 10, even in a case of the display apparatus 2 according to the present embodiment, the display apparatus 2 may include the display panel 10, the cover window 20, and the anti-reflection layer 30, and the anti-reflection layer 30 may include the first layer 31 and the second layer 32.

The first layer 31 of the anti-reflection layer 30 included in the display apparatus 2 according to the present embodiment does not include a plurality of holes H, but may include the plurality of grooves G. The plurality of grooves G may have a similar shape to the plurality of holes H. For example, the groove G may have a cross-sectional shape of a truncated cone. Specifically, the groove G may be formed at on the fourth surface 31S2. In other words, the groove G may be disposed open to outside the first layer 31 at the fourth surface 31S2. The plurality of grooves G may be disposed to each be open to outside the first layer 31, at the fourth surface 31S2. However, the groove G may not pass through both the third surface 31S1 and the fourth surface 31S2. A thickness portion of material forming the first layer 31 may be between a bottom of the groove G and the third surface 31S1, such thickness portion defining the third surface 31S1.

As shown in FIG. 11, a cross-sectional area of the groove G may have a circular shape on a cross section perpendicular to the thickness direction of the display apparatus 1 (e.g., the z-axis direction). However, the cross-sectional area of the groove G may decrease or increase in the thickness direction (e.g., the z-axis direction).

Referring back to FIG. 10, for example, the cross-sectional area of the groove G may decrease in the direction toward the third surface 31S1 from the fourth surface 31 S2. Accordingly, the cross-sectional area of the groove G at the fourth surface 31S2 may be largest among the cross-sectional areas of the groove G positioned along a depth of the groove G. Alternatively, the cross-sectional area of the groove G may increase in the direction toward the third surface 31S1 from the fourth surface 31S2. Accordingly, the cross-sectional area of the groove G at the fourth surface 31S2 may be narrowest among the cross-sectional areas of the groove G positioned along a depth of the groove G. The groove G included in the first layer 31 may not be filled with another layer (or material) disposed over or under the first layer 31. In other words, the groove G included in the first layer 31 may be a void or a gap. In an embodiment, the groove G may have a cylindrical shape along an entirety of the depth of the groove G.

A thickness portion of material forming the first layer may be defined coplanar with the plurality of groove G. These plurality of grooves G together with such thickness portion may have a shape similar to a honeycomb. Accordingly, even when the display apparatus 2 is folded and stress is applied to the anti-reflection layer 30, the stress applied to the anti-reflection layer 30 may be released. Thus, the durability of the anti-reflection layer 30 may not be weak.

A size D2 of the groove G may be about 1 nm or more to less than about 10 μm. The size D2 of each of the plurality of grooves G may be about 1 nm or more to less than about 10 μm. Herein, the size D2 of the groove G refers to dimension (e.g., a diameter) of a cross-sectional area of the groove G at a position where the cross-sectional area of the groove G is minimum. For example, when the cross-sectional area of the groove G decreases in the direction toward the third surface 31S1 from the fourth surface 31S2, the size D2 of the groove G may be a diameter of the cross-sectional area of the groove G on a plane which is coplanar with the bottom of the groove G and adjacent to the third surface 31S1. Alternatively, when the cross-sectional area of the groove G increases in the direction toward the third surface 31S1 from the fourth surface 31S2, the size D2 of the groove G may be a diameter of the cross-sectional area of the groove G at the fourth surface 31S2.

When the size D2 of the groove G is less than 1 nm, the groove G is so small that a stress release effect may not occur. When the size D2 of the groove G is more than 10 μm, the durability of the anti-reflection layer 30 may be reduced since the groove G is too large.

A distance L2 between adjacent grooves G from among the plurality of grooves G may be about 1 nm or more to less than 10 μm. Herein, the distance L2 between the grooves G refers to a shortest distance between one side of one groove G and one side of another groove adjacent to the groove G. Such shortest distance is defined at various locations along the depth of the groove G. The distance L2 may be a width of the solid portion of the first layer 31 which is between adjacent grooves G.

Hereinbelow, for convenience, one groove G is referred to as a first groove, and another groove G adjacent to the groove G is referred to as a second groove. For example, when cross-sectional areas of both the first groove and the second groove decrease in the direction toward the third surface 31S1 from the fourth surface 31S2, the shortest distance between the first groove and the second groove may be a shortest distance between one side of the first groove at the fourth surface 31S2 and one side of the second groove at the fourth surface 31 S2. Alternatively, when cross-sectional areas of both the first groove and the second groove increase in the direction toward the third surface 31 S1 from the fourth surface 31S2, the shortest distance between the first groove and the second groove may be a shortest distance between one side of the first groove at the fourth surface 31S2 and one side of the second groove at a plane adjacent to the third surface 31S1 (e.g., at bottoms of the first and second grooves).

Alternatively, when the cross-sectional area of the first groove decreases as the groove moves in the direction toward the third surface 31S1 from the fourth surface 31 S2 and the cross-sectional area of the second groove increases in the direction toward the third surface 31S1 from the fourth surface 31S2, the shortest distance between the first groove and the second groove may be the shortest distance between one side of the first groove at a plane adjacent to the third surface 31S1 and one side of the second groove at a plane adjacent to the third surface 31S1 or the shortest distance between one side of the first groove at the fourth surface 31S2 and one side of the second groove at the fourth surface 31 S2. Similarly, when the cross-sectional area of the first groove increases in the direction toward the third surface 31 S1 from the fourth surface 31S2 and the cross-sectional area of the second groove decreases in the direction toward the third surface 31S1 from the fourth surface 31S2, the shortest distance between the first groove and the second groove may be the shortest distance between one side of the first groove at the third surface 31S1 and one side of the second groove at the third surface 31S1 or the shortest distance between one side of the first groove at the fourth surface 31 S2 and one side of the second groove at the fourth surface 31S2.

When the distance L2 of the adjacent grooves G is less than 1 nm, the durability of the anti-reflection layer 30 may be reduced due to too many grooves G. When the distance L2 of the adjacent grooves G is more than 10 μm, the number of grooves G is so small that a stress release effect may not occur. As described above, a layer including an inorganic insulating material or the like may be formed through a chemical vapor deposition process or the like, and deposition conditions may be appropriately adjusted to adjust the presence or absence of grooves in this layer, sizes of the grooves, or a distance between the grooves. The adjustment of the presence or absence of grooves in the layer including an inorganic insulating material or the like, the sizes of the grooves, or the distance between the grooves by appropriately adjusting the deposition conditions is a common matter in the manufacturing of display apparatuses, and therefore redundant descriptions thereof are omitted.

According to one or more embodiments configured as described above, display apparatuses with improved durability may be implemented. However, the scope of one or more embodiments is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a display element;
a cover window on the display panel; and
an anti-reflection layer on the cover window, the anti-reflection layer comprising:
a first layer having a refractive index,
a second layer on the first layer and having a refractive index less than the refractive index of the first layer,
the first layer comprising a first surface facing the second layer and a second surface facing the cover window, and
the first layer comprising a plurality of holes defined therein and open at both the first surface and the second surface.

2. The display apparatus of claim 1, wherein a material density of the second layer is greater than a material density of the first layer.

3. The display apparatus of claim 2, wherein each of the first layer and the second layer comprises at least one of silicon oxide, silicon nitride and titanium oxide.

4. The display apparatus of claim 2, wherein a size of each of the plurality of holes is about 1 nanometer to about 10 micrometers.

5. The display apparatus of claim 2, wherein within the first layer, a distance between adjacent holes among the plurality of holes is about 1 nanometer to about 10 micrometers.

6. The display apparatus of claim 2, wherein the second layer excludes a void having a size of about 1 nanometer or more.

7. The display apparatus of claim 2, wherein the anti-reflection layer further comprises a third layer which is between the first layer and the second layer and comprises at least one of silicon oxide, silicon nitride and titanium oxide.

8. The display apparatus of claim 7, wherein the third layer comprises a plurality of sub-layers.

9. The display apparatus of claim 7, wherein the third layer has a refractive index which is less than the refractive index of the first layer and greater than the refractive index of the second layer.

10. The display apparatus of claim 2, wherein
the display apparatus is foldable, and
the display apparatus which is out-folded includes a portion of the first surface and another portion of the first surface facing in opposite directions.

11. A display apparatus comprising:
a display panel comprising a display element;
a cover window on the display panel; and
an anti-reflection layer on the cover window, the anti-reflection layer comprising:
a first layer having a refractive index,
a second layer on the first layer and having a refractive index less than the refractive index of the first layer,
the first layer comprising a first surface facing the second layer and a second surface facing the cover window, and
the first layer comprising a plurality of grooves defined therein and open at the second surface.

12. The display apparatus of claim 11, wherein a material density of the second layer is greater than a material density of the first layer.

13. The display apparatus of claim 11, wherein each of the first layer and the second layer comprises at least one of silicon oxide, silicon nitride and titanium oxide.

14. The display apparatus of claim 11, wherein a size of each of the plurality of grooves is about 1 nanometer to about 10 micrometers.

15. The display apparatus of claim 11, wherein a distance between adjacent grooves from among the plurality of grooves is about 1 nanometer to about 10 micrometers.

16. The display apparatus of claim 11, wherein the second layer excludes a void having a size of about 1 nanometer or more.

17. The display apparatus of claim 11, wherein the anti-reflection layer further comprises a third layer which is between the first layer and the second layer, and comprises at least one of silicon oxide, silicon nitride and titanium oxide.

18. The display apparatus of claim 17, wherein the third layer comprises a plurality of sub-layers.

19. The display apparatus of claim 17, wherein the third layer has a refractive index which is less than the refractive index of the first layer and greater than the refractive index of the second layer.

20. The display apparatus of claim 11, wherein
the display apparatus is foldable, and
the display apparatus which is out-folded includes a portion of the first surface and another portion of the first surface facing in opposite directions.

21. A display apparatus comprising:
a display panel comprising a display element;
a cover window on the display panel; and
an anti-reflection layer on the cover window, the anti-reflection layer comprising:
a plurality of layers each having a refractive index;
the refractive index of an outermost layer among the plurality of layers being less than all remaining refractive indices, and
an innermost layer among the plurality of layers being closest to the display panel and including a plurality of voids defined therein.

22. The display apparatus of claim 21, wherein
the innermost layer includes a first surface facing the outermost layer and a second surface facing the cover window, and
the plurality of voids which are defined in the innermost layer includes a plurality of holes each open at both the first surface and the second surface.

23. The display apparatus of claim 21, wherein
the innermost layer includes a first surface facing the outermost layer and a second surface facing the cover window, and
the plurality of voids which are defined in the innermost layer includes a plurality of grooves each open at the second surface.

24. The display apparatus of claim 21, wherein the innermost layer forms an interface with the outermost layer.

25. The display apparatus of claim 21, wherein
the innermost layer forms an interface with a layer closest thereto among the plurality of layers, and
a thickness portion of the innermost layer is between the layer closest thereto and each of the voids.
